(19) United States
(12) Patent Application Publication
(10) Pub. No.: US 2006/0043463 A1
(43) Pub. Date: Mar. 2, 2006

(54) Floating gate having enhanced charge retention

(75) Inventors: Chi-Wen Liu, Hsinchu (TW); Kuo-Ching Chiang, Tao-Yuan City (TW); Horng-Huei Tseng, Hsin-Chu (TW); Wen-Tin Chu, Kaohsiung County (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/932,198

(22) Filed: Sep. 1, 2004

(51) Int. Cl. H01L 29/788

(52) U.S. Cl. 257/316

(57) ABSTRACT

A semiconductor device includes a source and a drain formed in a substrate, a tunneling dielectric formed on the substrate between the source and the drain, and a floating gate disposed over the tunneling dielectric having a band-gap energy less than the energy band-gap of silicon.

### BACKGROUND

Along with technological advances in the integrated circuits (IC) industry, minimum feature size in semiconductor wafers scales down every technology node. To accommodate such scaling-down without loss of performance and reliability, the gate oxide is gradually replaced or partially replaced by high dielectric constant (k) materials.

In particular, non-volatile memory (NVM) technologies desire a long charge retention time period. The use of high-k materials may reduce band-gap differences between the gate dielectric (tunneling dielectric or tunneling oxide) and the floating gate. The reduced band-gap differences may lead to high leakage and degraded charge retention time of the NVM devices.

### BRIEF DESCRIPTION OF THE DRAWINGS

FIG. 1 is a schematic diagram of exemplary structure illustrating an embodiment of the present disclosure.

FIG. 2 is a sectional view of one embodiment of an integrated circuit constructed according to aspects of the present disclosure.

### DETAILED DESCRIPTION

The present disclosure relates generally to the field of semiconductor integrated circuits, more particularly, to a device having a floating gate and a method of fabricating such device.

It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

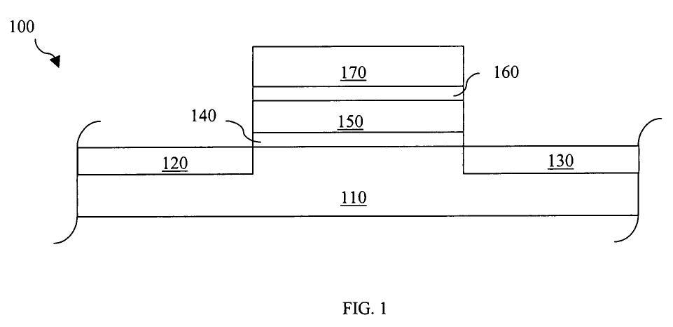

Referring to FIG. 1, in one embodiment, a schematic diagram of an exemplary device 100 illustrates a particular implementation of the present disclosure. The device 100 includes a substrate 110, which may be a semiconductor substrate. The substrate 110 may be an elementary semiconductor such as silicon, germanium, and diamond. The substrate 110 may also comprise a compound semiconductor such as silicon carbide, gallium arsenic, indium arsenide, and indium phosphide. The substrate 110 may comprise an alloy semiconductor such as silicon germanium, silicon germanium carbide, gallium arsenic phosphide, and gallium indium phosphide. The substrate may include an epitaxial layer. For example, the substrate may have an epitaxial layer overlying a bulk semiconductor. Further, the substrate may be strained for performance enhancement. For example, the epitaxial layer may comprise semiconductor materials different from those of the bulk semiconductor such as a layer of silicon germanium overlying a bulk silicon, or a layer of silicon overlying a bulk silicon germanium formed by a process including selective epitaxial growth (SEG). Furthermore, the substrate 110 may comprise a semiconductor-on-insulator (SOI) structure. For examples, the substrate may include a buried oxide (BOX) layer formed by a process such as separation by implanted oxygen (SIMOX). The substrate 110 may comprise a p-type doped region and/or an n-type doped region. For example, the substrate 110 may include p-type dopants for an n-type metal-oxide-semiconductor (NMOS) transistor or n-type dopants for a p-type metal-oxide-semiconductor (PMOS) transistor. All doping may be implemented by a process such as ion implantation. The substrate 110 may also comprise a well structure such as a P-well and an N-well structure, which may be fabricated directly onto or within the substrate 110. The above exemplary materials are provided as examples and are not meant to limit the disclosure in any manner.

The device 100 may include a source region 120 and a drain region 130 formed in the substrate 110. The source and drain regions 120 and 130 may be doped in a predefined profile and dopant concentration for optimized device performance according to desired applications. The doping dose may range from about 1×10¹⁹ atoms/cm² to about 5×10²⁰ atoms/cm², for example. The source and drain each may include a light doped region (also referred to as light doped drain or LLD). The source and drain may be formed by a process including ion implantation. The dopants may include boron and indium for a PMOS transistor, and phosphorus for an NMOS transistor.

The device 100 may include a gate structure comprising a tunneling dielectric (tunneling oxide) 140 and a floating gate 150. The tunneling dielectric 140 may be aligned horizontally interposed between the source and drain regions. The tunneling dielectric 140 may comprise a high dielectric constant (k) material such as silicon nitride, silicon oxynitride, hafnium oxide, hafnium silicide, hafnium silicon oxide, hafnium silicon oxynitride, zirconium oxide, aluminum oxide, hafnium dioxide-alumina (HfO₂—Al₂O₃) alloy, tantalum oxide, and/or combinations thereof. In general, the dielectric constant of the tunneling layer is greater than 4. The tunneling dielectric 140 may also comprise silicon oxide with high-k materials. The tunneling dielectric 140 may comprise a multi-layer structure. For example, the tunneling dielectric 140 may include a layer of silicon oxide disposed directly on the substrate 110 formed using a thermal oxidation process, and a layer of high-k material overlying the silicon oxide formed by atomic layer deposition (ALD), or another suitable method.

The floating gate 150 is positioned over the high-k tunneling dielectric. The floating gate 150 may comprise silicon, germanium, carbon, combinations such as SiGe, SiC, and SiGeC, or other suitable materials. Previously, when silicon floating gates were implemented with a high-k material, their band-gap energy difference is less than 7.78 eV, which is the band-gap energy difference of those devices prior to the employment of high-k tunneling materials. The material and composition for the floating gate 150 may be chosen to have an energy band-gap less than that of silicon (Eg=1.12 eV) to increase the band-gap difference between the high-k tunneling dielectric 140 and the floating gate 150 as much as possible. The increased band-gap energy difference between the tunneling dielectric and the floating gate prolongs the charge retention time of the floating gate. The floating gate 150 may be doped to enhance its conductivity using phosphorus, boron, or other suitable dopants. An exemplary doping dose may range from about 1×10¹⁸ atoms/cm² to about 1×10²⁰ atoms/cm². An exemplary thickness of the floating gate 150 may be greater than 100 Angstrom. The floating gate 150 may be designed as a strip structure over the tunneling dielectric 140 as shown in FIG. 1. The floating gate strip may have a gate length substantially equal to that of the tunneling dielectric 140 and aligned therewith.

The tunneling dielectric 140 and the floating gate 150 may be formed on the substrate 110 by processes including forming a layer of dielectric, forming a layer of floating gate material, patterning the layer of dielectric and the layer of floating gate material by photolithography and etching, and other processes such as doping, nitrogen treatment, and/or annealing. Forming the layer of dielectric material may further include a process such as thermal oxide, atomic layer deposition (ALD), chemical vapor deposition (CVD), or physical vapor deposition (PVD). Forming the layer of floating gate material may include a process such as CVD, PVD, ALD, and other methods. The tunneling dielectric and the floating gate may be patterned along with a control oxide (control dielectric) 160 and a control gate 170 described later.

When high-k materials are used for the tunneling dielectric, a floating gate constructed of silicon may have a reduced charge retention time. The floating gate 150 described herein may comprise semiconductor materials such as SiGe, SiGeC, and Ge with an energy band-gap less than that of silicon, which increases the difference of energy band-gap between the tunneling dielectric 140 and the floating gate 150. The charge retention time is thereby enhanced accordingly. As an illustration, Table A lists a plurality of exemplary high-k materials for the tunneling dielectric 140 and several semiconductor materials having an energy band-gap less than that of silicon (Eg=1.12 eV), including silicon germanium and germanium. The band-gap difference between the floating gate 150 and the tunneling dielectric 140 are compared among all combinations for two sets of materials. Silicon germanium having a band-gap energy of 1 eV is used as an example. Electron voltage (eV) is the unit for the energy band-gap difference in the Table.

TABLE A
The Energy Band-gap Difference Comparison (Unit: eV)

| | Dielectric | Band-gap | Band-gap | Band-gap | Band-gap |
|---|---|---|---|---|---|
| | constant | energy | Difference | difference | difference |
| Material | (k) | (Eg) | with Si | with SiGe | with Ge |
| SiO₂ | 3.9 | 8.9 | 7.78 | 7.9 | 8.24 |
| Ta₂O₅ | 26 | 4.5 | 3.38 | 3.5 | 3.84 |
| ZrO₂ | 25 | 7.8 | 6.68 | 6.8 | 7.14 |
| HfO₂ | 24 | 5.7 | 4.58 | 4.7 | 5.04 |
| Al₂O₃ | 9 | 8.7 | 7.58 | 7.7 | 8.04 |
| Si₃N₄ | 7 | 5.1 | 3.98 | 4.1 | 4.44 |

The gate structure of the device 100 may further comprise the control dielectric 160 and the control gate 170 formed atop of the floating gate 150. The control dielectric 160 may be disposed over the floating gate 150 and interposed between the floating gate 150 and the control gate 170. The control dielectric 160 may comprise silicon oxide, silicon nitride, silicon oxynitride, and other appropriate dielectric materials including high-k material(s) used in the tunneling dielectric 140. The control dielectric 160 may be formed using a process substantially similar to that of the tunneling dielectric 140.

The control gate 170 may comprise doped polysilicon, metal, metal silicide, other conductive materials, or combinations thereof. The metal used for the control gate 170 may include copper, aluminum, tungsten, nickel, cobalt, tantalum, titanium, platinum, erbium, palladium, and/or other materials. The control gate 170 may be deposited using PVD such as sputtering and evaporation, plating, CVD such as plasma enhanced CVD (PECVD), atmospheric pressure CVD (APCVD), low pressure CVD (LPCVD), high density plasma CVD (HDPCVD) and atomic layer CVD (ALCVD), or other processes.

The gate structure having the tunneling dielectric 140, the floating gate 150, the control dielectric 160, and the control gate 170 may also have spacers (not shown). The gate spacers may comprise dielectric materials such as silicon nitride, silicon oxide, silicon carbide, silicon oxynitride, or combinations thereof. The spacers may also have a multi-layer structure. The spacers may be formed by depositing dielectric material and then anisotropically etching back, for example.

The semiconductor device 100 may be a non-volatile memory (NVM) device or a portion thereof. A NVM device may include erasable-programmable read-only memory (EPROM), electrically erasable-programmable read-only memory (EEPROM), and flash memory.

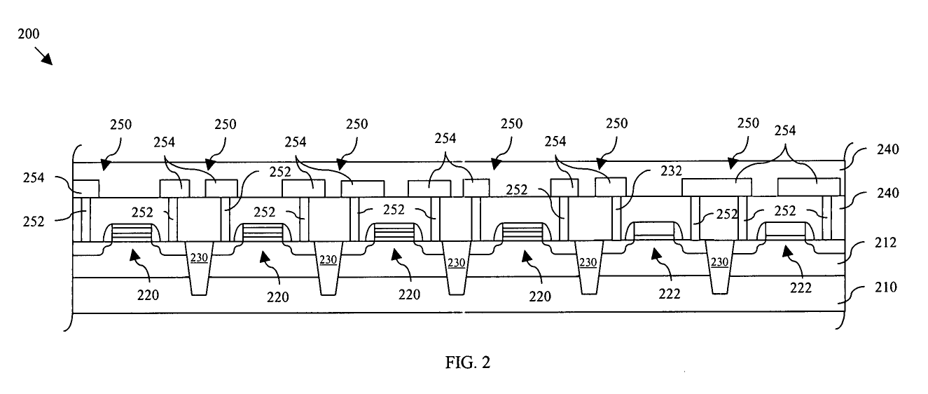

FIG. 2 is a cross-sectional view of one embodiment of an integrated circuit 200 in a substrate constructed according to aspects of the present disclosure. The integrated circuit 200 is one exemplary application of the semiconductor devices 100. The integrated circuit 200 may include a substrate 210 and may further include an epitaxial layer 212 formed using a semiconductor material either same to or different from the semiconductor materials used in the substrate 210. For example, the substrate 210 may comprise silicon and the epitaxial layer may comprise germanium, silicon germanium, or silicon germanium carbide. An exemplary method to form the epitaxial layer 212 may include selective epitaxial growth (SEG) processing. Furthermore, the substrate may be a semiconductor on insulator, such as silicon on insulator (SOI). The substrate may include a buried oxide layer (BOX).

In one example, the integrated circuit 200 may include a plurality of NVM devices 220, substantially similar to the semiconductor device 100 of FIG. 1 described above. The integrated circuit 200 may further include a plurality of other semiconductor devices such as an NMOS transistor and a PMOS transistor 222 integrated together with NVM devices 220. The semiconductor devices 220 and 222 may be isolated from each other in the substrate by an isolation feature 230 such as shallow trench isolation (STI) or local oxidation of silicon (LOCOS).

The integrated circuit 200 may also include multilayer interconnects 250 extending through dielectric layers 240 to ones of the plurality of the NVM devices 220 or other semiconductor devices such as MOS transistors 222. Furthermore, the sources, drains, and control gates of the semiconductor devices 220 may be directly wired to a multilayer interconnects 250 in a pre-designed configuration. The interconnects 250 may include contacts or via 252 and conductive line 254 employed to interconnect ones of the plurality of semiconductor devices 220 and 222, and/or to connect ones of the plurality of semiconductor devices 220 and 222 to other devices integral to or discrete from the integrated circuit 200. Materials used to from interconnects include copper, aluminum, aluminum alloy, tungsten, doped polysilicon, titanium, titanium silicide, tantalum, tantalum silicide, other conductive material, carbon nanotube (CNT), or combinations thereof. The interconnects may be formed by PVD, CVD, plating, ALD, and other processing including chemical mechanical polishing (CMP).

The dielectric layers 240 may comprise silicon oxide, phosphosilicate glass (PSG), borophosphosilicate glass (BPSG), fluorinated silica glass (FSG), low k materials and/or other suitable materials, and may be formed by CVD, spin-on glass (SOG), PVD, ALD and/or other processes such CMP. The dielectric layers 240 each may have a thickness ranging between about 500 nm and about 2000 nm, although the dielectric layers 240 are not limited by the scope of the present disclosure to particular thicknesses.

According to aspects of the present disclosure, each of the NVM devices 220 may include a tunneling dielectric similar to the tunneling dielectric 140 of FIG. 1, comprising high-k materials such as silicon nitride, silicon oxynitride, hafnium oxide, hafnium silicide, hafnium silicon oxide, hafnium silicon oxynitride, zirconium oxide, aluminum oxide, hafnium dioxide-alumina (HfO2—Al2O3) alloy, tantalum oxide, and/or combinations thereof. The tunneling dielectric may comprise a multi-layer structure. For example, the tunneling dielectric may include a layer of silicon oxide disposed directly on the substrate formed using a thermal oxidation process, and a layer of high-k material over the silicon oxide formed by a process such as ALD.

Each of the NVM devices 220 may include a floating gate similar to the floating gate 150 of FIG. 1, comprising silicon, germanium, carbon, other appropriate materials, or combination thereof. The material and composition for the floating gate may be tuned to have a energy band-gap less than that of silicon to increase band-gap difference between the tunneling dielectric and the floating gate. The floating gate may be doped using phosphorus, boron, or other appropriate dopants with an exemplary dopant concentration ranging from about 1×10¹⁸ atoms/cm² to about 1×10²⁰ atoms/cm². The thickness of the floating gate may be greater than 100 Angstrom in one embodiment.

The floating gate may be designed as a strip structure over the tunneling dielectric, as shown in NVM devices 220. The floating gate strip may have a gate length substantially equal to and aligned with the tunneling dielectric.

Each of the NVM devices 220 may further comprise a control dielectric and a control gate. The control dielectric and control gate may be substantially similar to those of the semiconductor device 100 of FIG. 1 in terms of material, structure, and processing. For example, the control dielectric may comprise silicon oxide, silicon nitride, silicon oxynitride, high-k material, and/or other suitable materials similar to those used for control dielectric 160 of FIG. 1. The control gate may include conductive materials and may have multilayer structure. The control gate may be silicon-containing, germanium-containing, metal-containing, or combinations thereof. The conductive material may comprise silicon, SiGe, metal, metal silicide, metal nitride, metal oxide, carbon nanotube, or a combination thereof. Each of the devices 220 may further include spacers disposed on both sides of the gate structure. The above exemplary materials are provided as examples are not meant to limit the disclosure in any manner.

The semiconductor devices 220 described herein may have a raised structure, multiple gates, and/or a strained channel. The semiconductor devices 220 each may be an EPROM, an EEPROM, or a flash memory cell. The semiconductor devices 220 and 222 may be fabricated using a P-well, or a dual-well structure, and may be fabricated directly onto or within the substrate.

It is understood that other device components and/or layers may be present in FIGS. 1 through 2 but are not shown for the purpose of clarity. Further, it is understood that the floating gate having a energy band-gap less than that of silicon is not limited to NVM devices and may be used to form other transistors or memory cell.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

What is claimed is:

1. A semiconductor device, comprising:
a source and a drain formed in a substrate;
a tunneling dielectric formed on the substrate between the source and the drain; and
a floating gate disposed over the tunneling dielectric having a band-gap energy less than the energy band-gap of silicon.

2. The semiconductor device of claim 1, wherein the floating gate comprises germanium.

3. The semiconductor device of claim 1, wherein the floating gate comprises silicon germanium.

4. The semiconductor device of claim 1, wherein the floating gate comprises silicon germanium carbide.

5. The semiconductor device of claim 1, wherein the floating gate comprises a dopant.

6. The semiconductor device of claim 5, wherein the dopant has a concentration ranging from about 1×10¹⁸ atoms/cm² to about 1×10²⁰ atoms/cm².

7. The semiconductor device of claim 1, wherein the floating gate comprises a phosphorus dopant.

8. The semiconductor device of claim 1, wherein the floating gate has a length substantially equal to the length of the tunneling dielectric.

9. The semiconductor device of claim 1, wherein the tunneling dielectric comprises a high-k material with k greater than 4.

10. The semiconductor device of claim 1, wherein the tunneling dielectric comprises silicon oxide.

11. The semiconductor device of claim 1, wherein the tunneling dielectric comprises hafnium oxide.

12. The semiconductor device of claim 1, wherein the tunneling dielectric comprises aluminum oxide.

13. The semiconductor device of claim 1, wherein the tunneling dielectric comprises tantalum oxide.

14. The semiconductor device of claim 1, wherein the floating gate has a thickness greater than 100 Angstrom.

15. The semiconductor device of claim 1, wherein the substrate comprises a strained semiconductor material.

16. The semiconductor device of claim 15, wherein the substrate comprises silicon germanium.

17. The semiconductor device of claim 15, wherein the substrate comprises silicon carbide.

18. The semiconductor device of claim 1 further comprising:
a control dielectric formed over the floating gate; and
a control gate formed over the control dielectric.

19. The semiconductor device of claim 18, wherein the control dielectric comprises a high-k material with a dielectric constant greater than 4.

20. The semiconductor device of claim 18, wherein the control gate comprises poly-silicon.

21. The semiconductor device of claim 18, wherein the control gate comprises metal.

22. A semiconductor device, comprising:
a source and a drain formed in a substrate;
a first dielectric formed on the substrate between the source and drain;
a floating gate formed on the first dielectric wherein the floating gate is characterized by a band-gap energy less than the energy band-gap of silicon;
a second dielectric formed over the floating gate; and
a control gate formed over the second dielectric.

23. The semiconductor device of claim 22, wherein the floating gate comprises germanium.

24. The semiconductor device of claim 22, wherein the floating gate comprises silicon germanium.

25. The semiconductor device of claim 22, wherein the floating gate comprises silicon germanium carbide.

26. The semiconductor device of claim 22, wherein the first dielectric comprises a high-k material with k greater than 4.

27. A method for fabricating a device on a semiconductor substrate, comprising:
forming a first dielectric with a dielectric constant greater than 4 on the semiconductor substrate;
forming a floating gate over the first dielectric having a band-gap energy less than the band-gap energy of silicon;
forming a second dielectric over the floating gate; and
forming a control gate over the second dielectric.

28. The method of claim 27, wherein forming the first dielectric comprises using an atomic layer deposition (ALD) process.

29. The method of claim 27, wherein forming a floating gate comprises forming germanium

30. The method of claim 27, wherein forming a floating gate comprises forming silicon germanium.

31. The method of claim 27, wherein forming a floating gate comprises forming silicon germanium carbide.

32. The method of claim 27, wherein forming a floating gate comprising forming the floating gate with doping concentration 1×10¹⁸ atoms/cm² to about 1×10²⁰ atoms/cm².

33. A semiconductor device, comprising:
an isolation region located in a substrate; and
a device located partially over a surface of the substrate, the device comprising
a tunneling dielectric formed on the substrate, having a material with dielectric constant greater than 4;
a floating gate formed on the tunneling dielectric, having a band-gap energy less than the band-gap energy of silicon;
a control dielectric formed on the floating gate; and
a control gate formed on the control dielectric.
